(19) United States
(12) Patent Application Publication
(10) Pub. No.: US 2026/0235657 A1
(43) Pub. Date: Aug. 13, 2026

(54) APPARATUS AND METHOD FOR MONITORING CONTAMINATIONS ON DISCHARGE ELECTRODES

(71) Applicants: Franz Knopf, Glenview, IL (US); ILLINOIS TOOL WORKS INC., Glenview, IL (US)

(72) Inventors: Franz KNOPF, Bühl (DE); Matthias HECHT, Lörrach (DE)

(21) Appl. No.: 19/154,223

(22) PCT Filed: Jan. 11, 2024
(86) PCT No.: PCT/US2024/011161

§ 371 Date: Aug. 6, 2025

(30) Foreign Application Priority Data
Feb. 8, 2023 (DE) 102023103041.8

(51) Int. Cl. G01R 31/14; G01R 31/12; G08B 21/18; H01T 19/04; H01T 23/00

(52) U.S. Cl. CPC G01R 31/14; G01R 31/1227; G08B 21/182; H01T 19/04; H01T 23/00

(57) ABSTRACT

Disclosed example apparatus for monitoring contaminations on discharge electrodes (3, 4, 5, 6, 7, 8), having at least one emission peak (32) that serves for the touchless discharge of electrically charged surfaces include: an earth terminal (21) that is or can be connected to the discharge electrode (3, 4, 5, 6, 7, 8); and a control device (27) configured to: detect a partial current coupled from the at least one emission peak to the earth terminal; determine an active power based on the partial current (i1(t), i2(t), i3(t)); and generate a status signal based on the calculated active power (i1(t), i2(t), i3(t)).

### RELATED APPLICATIONS

This international application claims priority to German (DE) Patent Application No. 102023103041.8, filed Feb. 8, 2023. The entirety of German (DE) Patent Application No. 102023103041.8 is incorporated herein by reference.

### TECHNICAL FIELD

The present disclosure relates to an apparatus for monitoring contaminations on discharge electrodes. According to a further aspect, the present disclosure relates to a method for monitoring contaminations on discharge electrodes.

### BACKGROUND

Passive and active discharge electrodes or active charging electrodes are known in a variety of embodiments and variations. Often, such electrodes have several emission peaks, which are arranged in different grid widths in a single row, in two rows, or also as a laminarly formed emission peak array, such that they resemble, for example, a fakir board. Very often, such emission peaks are embedded in elongated U-profiles by means of insulating casting resin together with a current-limiting resistor. The electrical resistor is associated with either each single tip or also with n-peaks. Passively acting discharge electrodes are often used in practice even without current-limiting resistors.

In the presence of an electrical field, the highest possible electrical field strength is to be effective at the peaks in case of an arrangement of emission peaks of active and passive high-voltage electrodes. In addition to complying with further boundary conditions, the respective peak would have to protrude sufficiently far from the insulating embedding. This is certainly comparable to the necessarily free-standing end of a lightning conductor over the object to be protected.

By applying a high voltage and the associated high electrical field strength, there is a corona discharge at the emission peaks, which is an electrical discharge in a non-conductive medium, for example air. Such corona dis-charges can be employed in a variety of applications. By way of example, the electrical surface treatment of plastic foils, paper, and aluminum foils is mentioned here, in which an insulator surface is evenly electrically charged. On the other hand, electrostatically-charged surfaces of insulating materials can be touchlessly discharged in that the emission peaks of the discharge electrodes emit bipolar gas ions and electrons via corona discharge.

One example of a discharge electrode with emission peaks known from the prior art can be found in EP 3 248 254 B1. According to the discharge electrode illustrated herein, a plurality of emission peaks are arranged in an insulated manner in a metal carrier profile, wherein the metal profile is connected to an earth terminal. In alternative design variants, the emission peaks are arranged in a plastic profile comprising an embedded metallic conductor, which in turn is connected to the earth terminal.

In practice, when such discharge electrodes are used, there is inevitably contamination of one or more emission peaks of the discharge electrode. The contamination can be, for example, dry particles such as dust, which are deposited on the emission peaks. For example, these can be referred to as insulating contamination, as they result in a reduction of the amount of free bipolar ions required for function, up to total loss of function. This also applies to the passively acting portion of such discharge electrodes.

Conversely, there is also so-called conductive contamination of the surface of the discharge electrode, when there are creepage current paths from the emission peak operated with high voltage to the nearest machine ground. This can arise, for example, from moisture deposits connecting the emission peaks to a conductive portion of the housing of the discharge electrode. Such creepage current paths on the one hand lead to significant power losses and on the other hand can lead to destruction of the entire discharge electrode, with often serious consequences for the respective production process in which the electrode is used. The low-impedance connection caused by the creepage current path of even one emission peak with the ground potential of the machine ground may result in the functional failure of the entire discharge electrode. In extreme cases, a fire of the discharge electrode can occur. If the carrier profile is made of conductive material or equipped with a high-ohmic surface coating, creepage current-related destructions of the carrier profile are preventable, but the temporary local functional failure of affected emission peaks is still given until required cleaning.

### SUMMARY

Based on the aforementioned problem, the industry requires that both the occurrence and the type of contamination are gradually detected with the highest possible sensitivity. Industry 4.0 and the associated intelligent networking of machines and processes in the industry are increasingly benefiting from such failure detection systems, which enable automatic fault elimination. For example, the respective discharge electrode can be switched off at times in order to avoid a fire incident or total failure of the system.

One problem addressed by the present disclosure is to provide an apparatus for monitoring contaminations on discharge electrodes, through which necessary maintenance can be detected in a timely manner, in particular before an expected failure of the discharge electrode.

According to the disclosure, the aforementioned problem is solved by an apparatus according to independent claim 1. A corresponding method is specified in independent claim 15. Advantageous further developments of the solution according to the disclosure are recited in the subclaims.

Accordingly, the disclosure relates to an apparatus for monitoring contaminations on discharge electrodes having at least one emission peak, which serves for the touchless discharge of electrically charged surfaces, wherein the apparatus comprises the following:
an earth terminal that is or can be connected to the discharge electrode;
a control device, wherein the control device is configured for the following purposes:
detecting a partial current coupled from the at least one emission peak to the earth terminal;
generating a status signal based on the detected partial current.

### BRIEF DESCRIPTION OF THE DRAWINGS

The present disclosure will be described in further detail below with reference to the embodiments shown in the figures. The following are shown:

FIG. 1 is a schematic diagram of an apparatus for monitoring contaminations on discharge electrodes according to the present invention for discharge electrodes having metal profiles;

FIG. 2 is a schematic, idealized representation of current, voltage, and instantaneous power curve as well as the calculated active power as the average of the instantaneous powers over a period; and

FIG. 3 is a schematic diagram of an apparatus for monitoring contaminations on discharge electrodes, according to a further embodiment, for monitoring discharge electrodes with insulatedly embedded conductors.

### DETAILED DESCRIPTION

Disclosed methods and apparatus for monitoring contaminations on discharge electrodes are based on the idea that the active power received by the individual discharge electrodes is variable due to contamination. Accordingly, based on the change in active power, inferences can be drawn regarding the contamination of the discharge electrodes and the associated emission peaks. However, there are some problems that make such monitoring of active power seem unattractive. In particular, the active power is only minimally affected by the insulating contamination, for example by dusting of the emission peaks. Below the noise level of the currents resulting from the passive and active discharge, this is thus substantially not detectable, or detectable only too late. Also, to detect the total active power of a plurality of discharge electrodes of an ionization system, it would be necessary to provide a separate transformer per discharge electrode in order to be able to determine the active power of the individual discharge electrodes.

The present invention bypasses the problems described above in that only partial currents are measured which flow between the emission peaks of the discharge electrode and the earth terminal of the apparatus. In normal operation, i.e., when there is no conductive contamination or not too much insulating contamination, such partial currents are caused by a capacitive coupling between the emission peaks and the metal profile carrier or between the emission peaks and the insulatedly embedded conductor, as will be explained in further detail in relation to the drawings. The partial currents generated by the capacitive coupling are only based on the alternating currents caused by the alternating voltage, because a passive discharging via the emission peaks leads to a DC current, which can have no influence in the case of capacitive coupling. Accordingly, the partial current is also free of the relatively high current fractions generated by the passive discharge. The signal for the partial current obtained thereby is high-resolution and can thus be used in order to detect even the smallest contaminations, i.e., an active power drop of about 1% of the maximum possible useful signal or less.

It is known to the person skilled in the art that if the emission peaks are insulatedly contaminated, there is a slow (often for weeks and months) decrease in active power. As will be explained in further detail below, a decrease in active power can be used in order to draw conclusions about the contamination.

It should be mentioned that the partial currents flowing between the emission peaks and the earth terminal of the apparatus can also occur in some situations, regardless of the capacitive coupling. For example, these can be creepage currents that occur when there is conductive contamination between the emission peaks and the earth terminal. For example, moisture deposits between the peaks and the metal profile carrier can cause creepage currents between the peaks and the carrier to occur, which rapidly increase the detected partial currents and the associated active power. Based on the aforementioned partial currents, not only insulating contaminations but also conductive contaminations, such as moisture, can thus be inferred.

To detect the partial current, the control device can be configured so as to receive/request different data/parameters. For example, this data can include a voltage drop over a reference resistor arranged between the emission peak and the earth terminal. It should be noted that the invention is not limited to the manner in which the partial current is detected. Rather, the idea behind the invention is to use the partial current in this way as a parameter for contamination of the discharge electrode.

According to a further embodiment, the control device is configured so as to:
calculate an active power based on the partial current;
generate a status signal based on the calculated active power.

To calculate the active power, the control device according to one embodiment is configured so as to determine the average value of the product of the instantaneous values of a partial current and the supply voltage, measured on the secondary side of the transformer, i.e., the average value of the instantaneous powers. On the one hand, the control device can be configured so as to determine the product of secondary voltage and partial current analogously. On the other hand, it is of course also possible for the control device to digitally determine the product of voltage and current.

According to a further embodiment, the control device is configured so as to:
compare the calculated active power to a first active power reference value;
generate the status signal based on the comparison between the calculated active power and the first active power reference value.

The active power reference value can be an expected active power that is achieved when the discharge electrode is clean, i.e., without significant contamination. Of course, this value is a parameter that is dependent on many factors, for example the number of emission peaks as well as the materials used and the state of the discharge electrode. Accordingly, the active power reference value of each discharge electrode can be calibrated at the factory or also by the user.

In a further embodiment, the active power reference value can also be changed automatically or manually in order to account for wear on the discharge electrode over time. In other words, over time, the current flowing between the emission peaks and the ground can change (e.g., decrease) without being caused by contamination of the discharge electrode. For example, to take into account this temporal change in the expected active power value, the user can perform a calibration measurement of the active power after each cleaning of the electrode system and define the value thus generated as the new active power reference value. Of course, this can also be done automatically.

According to a further embodiment, the control device is configured so as to:
generate a first status signal that is representative of an insulating contamination if the calculated active power is below the first active power reference value; and/or
generate a second status signal that is representative of a conductive contamination if the calculated active power is above the first active power reference value.

As indicated above, a decrease in the active power versus the active power reference value can indicate insulating contamination, which also decreases the capacitive coupling between the emission peaks and the ground-connected portions of the discharge electrode. Accordingly, the partial current also changes, which is detected by the control device and ultimately leads to a reduction of the determined active power. In this case, the control device can output a status signal, i.e., if the determined active power is below the first active power reference value, which indicates an insulating contamination. This status signal can be output to the user via an optical or audible warning signal, for example. On the other hand, the status signal can additionally or alternatively be used in order to automatically clean the discharge electrode. This is likewise the case if the determined active power is above the first active power reference value. This can indicate a conductive contamination, for example excessive moisture on the discharge electrode. The second status signal can be used in order to inform the user accordingly or automatically take countermeasures.

In a further embodiment, the control device can also be configured so as to output the first status signal when a first active power reference value is exceeded and output the second status signal when a second active power reference value is exceeded. The second active power reference value can be significantly higher than the first active power reference value. This is particularly justified in that, in the case of a conductive contamination, the determined active power increases sharply as expected. By using two active power reference values, it can be prevented that insignificant changes in active power over the active power reference value will result in an unwanted error message.

According to a further embodiment, the apparatus comprises at least one discharge electrode resistor, via which a metal profile or an insulatedly embedded conductor is connected to the earth terminal, and wherein the apparatus is configured so as to measure a voltage drop via the discharge electrode resistor, wherein the control device is further configured so as to determine the partial current based on the voltage drop via the discharge electrode resistor. If the apparatus is to be used in order to monitor a plurality of discharge electrodes, the apparatus comprises at least one discharge electrode resistor per discharge electrode. The discharge electrode resistors are connected to the metal profile or the embedded conductor of the discharge electrode on the one hand and the earth terminal on the other hand. Accordingly, the partial current flowing through the capacitive coupling or the creepage currents between the emission peaks and the earth terminal can be determined by the discharge electrode resistors in a simple manner.

According to a further embodiment, the apparatus comprises a transformer, which can be connected on the secondary side to the discharge electrode, wherein the control device is connected to the transformer on the secondary side, in particular via a voltage divider, and is configured so as to determine the secondary voltage of the transformer. The voltage divider can be configured such that the voltage values output to the control device lie in the preferred operating range of the control device. The control device can determine the secondary-side voltage of the transformer based on the voltage output via the voltage divider and multiply it by the determined partial current, as mentioned above, in order to determine the active power. By connecting the control device to the secondary side of the transformer, the temporally changing voltage can also be considered by the control device. Fluctuations in the mains voltage thus cannot distort the measurement result, i.e., the determination of the active power.

According to a further embodiment, the apparatus is configured so as to simultaneously monitor a plurality of discharge electrodes, wherein the control device is configured so as to detect for each discharge electrode a partial current that is coupled from the at least one emission peak of the respective discharge electrode to the earth terminal. In other words, the apparatus is configured so as to detect a number of different partial currents that corresponds to the number of discharge electrodes to be monitored. On the hardware side, only one discharge electrode resistor per discharge electrode is necessary in order to set the apparatus to discharge electrodes that are to be monitored more or less.

According to a further embodiment, the control device is configured so as to detect the partial current capacitively coupled from the emission peak to the metal profile or to the insulatedly embedded conductor and consequently to the earth terminal.

According to a further embodiment, the detection of the partial current and thus the signal generation and evaluation for contamination detection can be carried out selectively and independently for any number of discharge electrodes.

According to a further embodiment, the control device is further configured so as to determine a contamination-based active resistance by quadrating the secondary voltage of a transformer divided by the contamination-dependent active power. The contamination-dependent active resistance determined in this way is in particular independent of possible mains voltage fluctuations.

According to a further embodiment, the detected partial current for generation of the status signal is independent of a DC component, which must flow to the ground upon discharge of highly charged surfaces via the emission peak and secondary coil of a transformer.

According to a further embodiment, the apparatus comprises a display for indicating the status signal in an analog or digital manner. For example, if the active power reference value mentioned above is not met, the user can be informed via the display that there may be insulating contamination on the discharge electrode. As already mentioned above, by independently assessing the individual partial currents, the apparatus can also inform the user as to which discharge electrode appears to be contaminated. The apparatus can also output further information via the display, for example in order to prompt the user to clean a particular discharge electrode.

According to a further embodiment, the apparatus comprises a plurality of discharge electrodes, wherein the status signal contains separate status data for each discharge electrode.

According to a further aspect, the present disclosure relates to a method for monitoring contaminations on discharge electrodes that serve for touchless discharge of electrically charged surfaces, wherein the discharge electrodes comprise at least one emission peak, and wherein the method comprises the following:
detecting a partial current coupled from the at least one emission peak to the earth terminal connected to the discharge electrode;
generating a status signal based on the detected partial current.

According to a further aspect, the present invention relates to a method for monitoring contaminations on discharge electrodes (3, 4, 5, 6, 7, 8) that serve for touchless discharge of electrically charged surfaces, wherein the discharge electrodes (3, 4, 5, 6, 7, 8) comprise at least one emission peak (32), and wherein the method comprises the following:
detecting a partial current (i1(t), i2(t), i3(t)) coupled from the at least one emission peak (32) to a ground (21) connected to the discharge electrode;
determining an active power based on the partial current (i1(t), i2(t), i3(t));
generating a status signal based on the calculated active power (i1(t), i2(t), i3(t)).

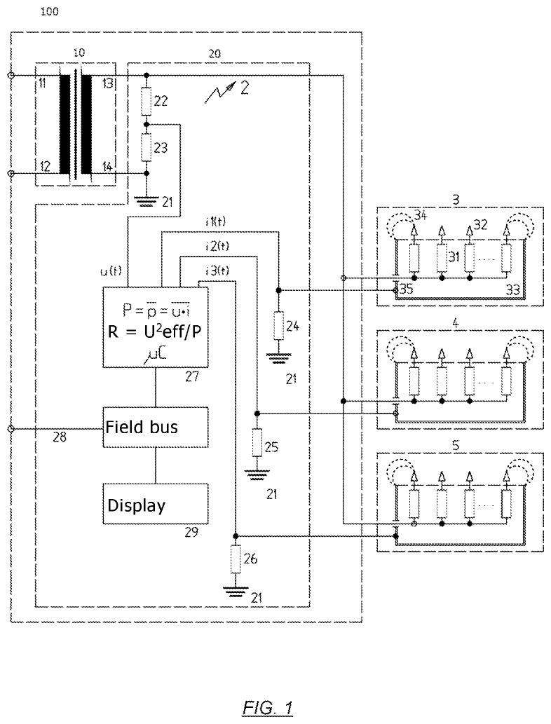

FIG. 1 shows a schematic diagram of an apparatus according to the invention for detecting contaminations on discharge electrodes. The apparatus 100, in the example of FIG. 1, is connected to three discharge electrodes 3, 4, 5. However, it should already be mentioned at this point that the apparatus 100 according to the invention is adaptable to any number of discharge electrodes 3, 4, 5.

The apparatus comprises a high-voltage transformer 10 and a measuring or evaluation assembly 20. The high-voltage transformer 10 is connected to the power network with its primary winding 11, 12 or to a variable-frequency and variable-voltage power unit (not shown). A first end of the secondary winding 13 is connected to the three discharge electrodes 3, 4, 5 via a high-voltage cable 2. The discharge electrodes 3, 4, 5 are generally AC high-voltage discharge electrodes or high-voltage ionizers.

The second end of the secondary winding 14 is connected to an earth terminal 21. The alternating high voltage delivered to the high-voltage cable 2 via the secondary winding is typically in the voltage range of 4 to 10 kV. Such high voltages are required in order to achieve a high electrical field strength with accompanying corona discharge at the emission peaks of the discharge electrodes 3, 4, 5. This corona discharge produces bipolar gas ions and free electrons by way of shock ionization. Such free charge carriers are capable of neutralizing positively or negatively charged surfaces or discharging their surfaces.

A portion of the alternating high-voltage of the transformer 10 provided on the secondary side is provided to a control device 27 via a voltage divider 22, 23 as an input signal. Accordingly, the voltage signal u(t) provided to the control device 27 is proportional to the alternating high-voltage prevailing in the high-voltage cable (2). As will be explained in further detail below, the voltage signal u(t) can be used by the control device 27 for determining the active power.

The control device 27 of the evaluation assembly 20 is further connected to a metallic portion of each of the discharge electrodes 3, 4, 5. In other words, the control device 27 is used in order to collect parameters and data providing information about a partial current of the discharge electrodes 3, 4, 5 flowing in the direction of the earth terminal 21. The partial current of the discharge electrode 3 is shown schematically here as “i1(t).” The partial current of the second discharge electrode 4 is shown schematically as “i2(t).” Finally, the partial current of the third discharge electrode 5 is shown schematically as “i3(t).” At this point, however, it should be mentioned that control device 27 does not need to be supplied with a direct measurement of the partial currents i1(t), i2(t), i3(t). Rather, any parameters or data that provide information about the partial currents flowing to the earth terminal 21 can be passed on to the control device 27.

As shown schematically in FIG. 1, the control device can for this purpose respectively multiply the voltage signal u(t) by the partial currents i1(t), i2(t), i3(t) and form an average value in order to determine the active power of the partial currents i1(t), i2(t), i3(t) caused by a coupling of the emission peaks to the earth terminal 21. In mathematical terms, the control unit can calculate the active power caused by the capacitive coupling or by the creepage currents as follows:

$$P = \frac{1}{T} {\int }_{{t}_{0}}^{{t}_{0} + T} u \cdot i dt$$

The capacitive coupling indicated above will be explained below in further detail. The discharge electrodes 3, 4, 5 shown in FIG. 1 are substantially identical. However, it should be noted that the arrangement and number of emission peaks can vary significantly between the discharge electrodes. Accordingly, the outlined arrangements according to FIG. 1 are to be considered schematic only. As an example, only the discharge electrode 3 of FIG. 1 will be described below.

The discharge electrode 3 has one or more emission peaks 32, each of which is associated with a current-limiting resistor 31. The emission peaks 32 and current-limiting resistors are embedded in a metal profile 33 by means of insulating casting compound, which serves as the carrier profile for the emission peaks. Preferably, this metal profile 33 has an insulating, stress-resistant surface. The current-limiting resistors 31 are connected to the high-voltage cable 2 of the apparatus 100 on the one hand and to the corresponding emission peak 32 on the other hand. Thus, a high electrical field strength with accompanying corona discharge at the emission peaks 32 can be produced by the alternating high voltage provided by the transformer 10. This corona discharge produces bipolar gas ions and free electrons by way of shock ionization. A portion of these charge carriers generated by the ionization current, and thus a portion of the active electrical power emitted by the emission peaks 32, is transmitted from the emission peaks 32 to the metal profile 33 via a schematically shown, dashed-shaped capacitive coupling 34.

The metal profile 33 of the discharge electrode 3 is connected to the earth terminal 21 of the apparatus 100 via an electrical terminal 35. A first discharge electrode resistor 24 is arranged between the electrical terminal 35 and the earth terminal 21, i.e., the ground. The same applies to the second and third discharge electrode resistors 25, 26, which are arranged between the second and third discharge electrodes 4, 5 and the earth terminal 21, respectively.

The voltage drop at the first discharge electrode resistor 24 is proportional to the ion-generating active current i1(t) of the first discharge electrode 3. This applies analogously to the discharge electrodes 4, 5 as well as the current measurement via the voltage drop at the discharge electrode resistors 25, 26. Accordingly, as needed, any number of discharge electrodes can be monitored (not shown). In summary, it remains to be noted that the discharge electrode resistors 24, 25, 26 (for example, by determining the voltage drop) serve to determine the respective partial current, which is coupled via the capacitive coupling 34 of the emission peaks 32 to the metal profile 33 and thus to the earth terminal 21.

It has been found that the capacitively coupled currents of the discharge electrodes 3, 4, 5 are dependent on the contamination of the discharge electrodes. For example, in the case of an insulating contamination, i.e., in the case of dusting of the emission peaks, a change in the partial currents i1(t), i2(t), i3(t) or the active power associated therewith can be detected. Accordingly, the separately provided discharge electrode resistors 24, 25, 26 make it possible to detect insulating contaminations on each individual discharge electrode 3, 4, 5 separately.

However, the apparatus 100 is not only able to detect partial currents generated via the aforementioned capacitive coupling 34. Rather, creepage currents can also be determined between the emission peaks 32 and the metal profile 33. Such creepage currents are created, for example, by undesired low-impedance compounds between the emission peaks and the metal profile 33, as can in particular be created by moisture deposits at the emission peaks. Such creepage currents are typically many times higher than the partial currents generated by the capacitive coupling 34. In other words, in the case of conductive contamination (for example, too high a moisture at the emission peaks), there are partial currents i1(t), i2(t), i3(t) towards the earth terminal 21 whose active current fractions are significantly higher than the partial currents i1(t), i2(t), i3(t) generated by the capacitive coupling 34. As will be explained in further detail below, the control device 27 can accordingly infer conductive contamination of one or more of the discharge electrodes 3, 4, 5 upon a sudden change in one or more of the partial currents i1(t), i2(t), i3(t).

The high sensitivity of the partial currents allows early detection and indication of the contamination state even with a minor change in the emission performance of the discharge electrodes. Thus, reliable planning for preventive maintenance without undesirable machine downtimes can be achieved by means of the status signal based on the partial currents i1(t), i2(t), i3(t), which is generated by the control device 27. The signal is unique and only assigned to the electrode that is insulatedly or conductively soiled.

The apparatus 100 further comprises a field bus terminal 28 on which the control device 27 is connected with a bi-directionally operating connection. Accordingly, the status signal generated by the control device 27 can be output to any process environment for higher-level quality assurance or the general provision of the data within the meaning of industry standard 4.0. For this purpose, the apparatus 100 can have an interface (not further discussed).

In the embodiment of the apparatus 100 shown in FIG. 1, there is further provided a display 29 via which data of the control device 27 can be output. For example, a display 29 or visualization of the degree of contamination is carried out numerically or graphically. For example, the status signal of the control device 27 can be used in order to issue warnings via the display to the user if a conductive or insulating contamination has been detected by the control device 27. The output can further inform the user as to which of the discharge electrodes 3, 4, 5 is/are affected. In a further embodiment, the status signal of control device 27 can also include information or suggestions for remediating the contaminations. Alternatively or additionally, the status signal generated by the control device 27 can also be used in order to initiate an automatic cleaning of the respective discharge electrode 3, 4, 5.

In the following, the method for generating a status signal, which is representative of the contamination state of the discharge electrodes, is explained in further detail.

As already mentioned above, the alternating high voltage provided in the high-voltage cable 2 results in a high electrical field strength at the emission peaks with associated corona discharge. A portion of the emitted electronic charge carriers and thus a portion of the emitted electrical active power are transmitted from the emission peaks 32 to the metal profile 33 via the capacitive coupling 34. Such charge carriers are dissipated in the form of a partial current i1(t) in the direction of the earth terminal 21. The current flow/partial current i1(t) resulting therefrom can be detected via a voltage drop on the discharge electrode resistor 24.

The control device 27 is configured so as to multiply the thusly detected current strength of the partial current i1(t) by the voltage signal u(t) and to form a mean value of the product in order to determine the portion of the emitted active electrical power that is transmitted to the metal profile via capacitive coupling.

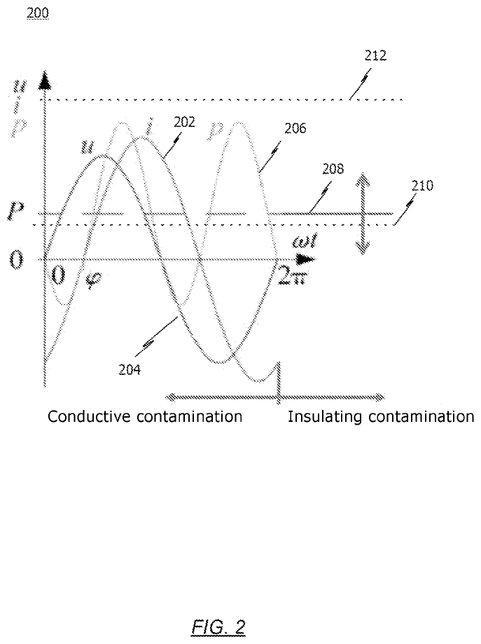

In this context, reference is also made to FIG. 2. In FIG. 2, a schematic, idealized graph of the current, voltage, and instantaneous power signal, as well as the active power curve is shown. In the schematic representation according to FIG. 2, the voltage signal (u(t)) and the current signal (i(t)) are shown in a purely sinusoidal manner. In reality, only the voltage signal approximately corresponds to the sinusoidal curve shown here. However, the current signal of the partial current 202 has a very high harmonic content, so that there is no sinusoidal curve. Accordingly, reference is merely schematically made to the illustration according to FIG. 2.

The signal of the instantaneous power 206 resulting from the multiplication of the voltage signal 204 and the current signal 202 is also schematically shown in FIG. 2. The control device is configured so as to calculate the average of the instantaneous powers (p) and thus the active power 208 (P). This can occur on the one hand by an analog circuit and on the other hand by a digital calculation, according to the integral described above. The control device compares the thusly calculated active power to an active power reference value.

Upon contamination of the discharge electrodes, there is a phase shift of the current signal relative to the voltage signal 204. The phase shift is indicated schematically in FIG. 2 by arrows. Thus, in the case of conductive contamination, which can generate creepage currents, there is a phase shift of the current signal towards the voltage signal and thus often a sudden jump in the active power 208. With insulating contamination, the phase difference between the voltage signal 204 and the current signal 202 of the partial current increases, so that there is a gradual reduction of the active power 208. It should be noted at this point that the monitoring of the active power (i.e., the change in active power), i.e., the calculation of the product of current and voltage and average value formation, is a particularly fast and reliable method for detecting a change in the phase shift between the current and voltage signals and thus drawing conclusions about the contamination of the discharge electrodes. It is also contemplated, however, that the phase shift can be detected solely on the basis of the current signal 202. This can be achieved, for example, by a Fourier analysis of the current signal, wherein a calculation of the active power is not absolutely necessary. Rather, in this case, the control unit can be configured so as to draw conclusions directly about the insulating or conductive contamination of the discharge electrodes based on the phase shift.

With regard to FIG. 2, it should be further noted that, in case of conductive or insulating contamination of the discharge electrodes, the amplitude of the current signal 202 does not change substantially, so that merely viewing the amplitude of the current signal 202 does not allow for meaningful conclusions to be drawn about the contamination of the discharge electrodes; this is above all the case with low-insulating contamination.

The control device 27 can be equipped with an active power reference value, which is determined at the factory, for example. The active power reference value is a value for the active power generated due to the capacitive coupling 34, which is to be expected in case of uncontaminated discharge electrodes. This can be determined at the factory, for example, by measurements of the uncontaminated discharge electrodes and stored in a memory of the control device 27. On the other hand, the active power reference value can also be changeable/adjustable by the user, as will be explained in further detail below.

The control device is configured so as to compare the active power based on the partial current i1(t) to the active power reference value. In so doing, a calculated active power, which is below the active power reference value, can be an indication that there is insulating contamination, as already stated above. The active power reference value can be a few percentage points lower than the actual expected active power in case of a clean discharge electrode, in order to generate an alert signal, that is to say a change in the status signal of the control device, only when a certain degree of contamination has already occurred. This can be provided in particular for compensation of natural fluctuations in the calculated active power.

The control device can be configured so as to generate a first status signal that is representative of an insulating contamination if the calculated active power is below the first active power reference value. By way of example, FIG. 2 shows a first active power reference value 210, which is below the active power 208 in the uncontaminated state.

The control device can generate a second status signal that is representative of a conductive contamination if the calculated active power is above the first active power reference value.

Because the expected active powers are fundamentally different in case of conductive or insulating contamination, the control device can also be equipped with a second active power reference value in addition to the first active power reference value. Accordingly, the control device can compare the calculated active powers, respectively, continuously, or in intervals, to the first active power reference value and the second active power reference value. If the calculated active power is below the first active power reference value, the control device generates the first status signal, which indicates an insulating contamination. In the event that the calculated active power is above the second active power reference value, the control device outputs the second status signal, which indicates a conductive contamination. The second active power reference value is preferably many times higher than the first active power reference value. Typically, the difference can be about a factor of 100.

According to a further design variant, the control device can also be configured so as to generate a difference between the active power and the first active power reference value and the second active power reference value, respectively. Based on the difference between the active power reference values and the calculated active power, the control device 27 can generate the status signal. For example, an active power that is below the first active power reference value results in a negative difference. The negative difference can be used by the control device in order to output the first status signal. Alternatively or additionally, the control device 27 can be configured so as to check whether the difference exceeds a certain threshold value. For example, it can be ensured that the first status signal is not generated until the calculated active power falls below the first active power reference value by a certain value or percentage. This is advantageous because the calculation of the active power according to the present invention is highly sensitive and can already detect very low contaminations of the discharge electrodes. Accordingly, in order not to unnecessarily inform the user about the smallest contaminations, the threshold value can be set on the user side. This can be set as a percentage via the display, for example, so that the first status signal is only generated with a significant deviation of the active power calculated from the first active power reference value (e.g., above 10%).

The control device can be configured accordingly in order to determine the difference between the calculated active power and the second active power reference value and use this difference, as described above in connection with the first active power reference value, to generate the second status signal. An exemplary second active power reference value 212 can also be seen in FIG. 2 and lies above the active power P in case of an uncontaminated discharge electrode.

If insulating contamination and conductive contamination simultaneously occur (e.g., because water is dropping onto the electrode), a clearly higher active power will always occur, so that the control unit outputs only the second status signal for the conductive contamination. Conductive contamination is generally the highest and thus first priority. Only when the discharge electrode has dried up again and the insulating contamination still exists would the control unit, upon the disappearance of the conductive contamination, output the first status signal for an insulating contamination.

It should be mentioned at this point that the expected active power, which is achieved in particular via the capacitive coupling 34, is variable over time due to wear on the discharge electrodes 3, 4, 5. Accordingly, it can be sensible to readjust the first active power reference value from time to time. For this purpose, the apparatus 100 can have interfaces for the user to enter new reference values. For example, the display 29 can be configured as a touch screen in order to input the desired active power reference value. The display can comprise a corresponding input mask for this purpose. Alternatively or additionally, the control device can be configured so as to automatically adjust the active power reference value at regular intervals. All that is required is an input from the user in order to confirm that the discharge electrode in question is free of contaminations. The control device can then perform a test operation of the respective discharge electrode in order to determine the corresponding active power of the now clean discharge electrode. The average of this active power can then be stored as the new first active power reference value.

Because the size and arrangement of the different discharging assemblies 3, 4, 5 can differ substantially from one another, it is generally contemplated that the control device has a corresponding first and/or second active power reference value for each discharge electrode to be monitored. The status signals generated by the control device can thus be adjusted to the circumstances of the different discharge electrodes 3, 4, 5, respectively. Thus, the signal generation and evaluation for contamination detection is selectively and independently possible for any number of discharge electrodes.

If discharge electrodes are operated with the apparatus 100 according to the invention against an electrically highly charged, moving substrate, a DC discharge current flow over the emission peaks 32 and the secondary winding 13, 14 of the transformer occurs, depending on the polarity of the substrate charging. However, such a DC discharge current flow does not lead to a capacitive coupling and is accordingly also not detected by the control device 27. Thus, the calculation of the active power according to the present invention is also independent of the very high DC discharge current flows, whereby the sensitivity of the proposed contamination detection can be further increased.

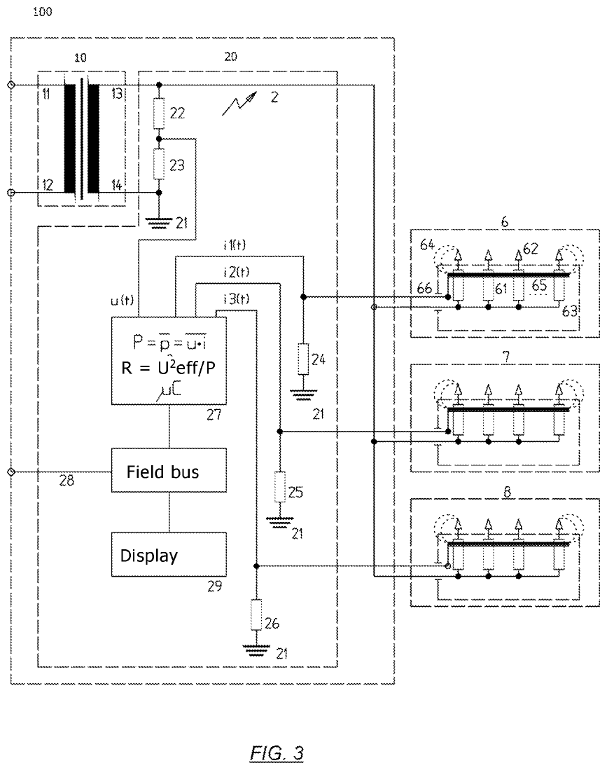

FIG. 3 is a schematic circuit diagram of the apparatus 100 according to the invention, in conjunction with a second type of discharge electrodes 6, 7, 8. In other words, the apparatus 100 is identical to the apparatus 100 according to FIG. 1. Only the discharge electrodes 6, 7, 8 of FIG. 3 monitored with the apparatus 100 are different from the discharge electrodes of FIG. 1. In particular, the discharge electrodes 6, 7, 8 of FIG. 3 are discharge electrodes having a carrier profile made of insulating material 63 with at least one embedded conductor 65 connected via an electrical terminal point 66 to the earth terminal 21 of the apparatus 100 via a conductor. The function of the discharge electrodes 6, 7, 8 shown in FIG. 3 with carrier profiles made of insulating material 63 is disclosed in detail in EP 096 862 881.

In the case of the discharge electrodes with carrier profiles made of insulating material, a portion of the charge carrier generated by the ionization current and emission peaks 62 and thus a part of the emitted active electrical power is transmitted via the capacitive coupling 64 to the conductor 65 embedded in the insulating material 63 and is thus discharged towards the earth terminal 21. The electrical connection of the conductor 65 to the earth terminal 21 is carried out via the resistor 24. The voltage drop at the resistor 24 is therefore in turn proportional to the ion-generating active current of the discharge electrode 6 and thus proportional to the active power. This applies analogously to the discharge electrodes 7, 8 as well as the current measurement via the voltage drop at the discharge electrode resistors 25, 26.

The operation of the control device 27 for determining the status signal is substantially identical to the operation already described in connection with FIG. 1. Accordingly, use of the apparatus on different discharge electrodes does not require any further change to the apparatus 100. Only the active power reference values of the discharge electrodes 6, 7, 8 differ substantially from the active power reference values of the discharge electrodes 3, 4, 5, according to FIG. 1.

The present disclosure is not limited to the embodiments presented in the figures, but rather results from combinations of all of the features disclosed herein.

1-14. (canceled)

15. An apparatus for monitoring contaminations on discharge electrodes having at least one emission peak, which serves for the touchless discharge of electrically charged surfaces, wherein the apparatus comprises:
an earth terminal that is or can be connected to the discharge electrode;
a control device, wherein the control device is configured to:
detect a partial current (i1(t), i2(t), i3(t)) coupled from the at least one emission peak to the earth terminal;
determine an active power based on the partial current (i1(t), i2(t), i3(t)); and
generate a status signal based on the calculated active power (i1(t), i2(t), i3(t)).

16. The apparatus according to claim 15, wherein the control device is further configured to:
compare the determined active power with a first active power reference value; and
generate the status signal based on the comparison between the determined active power and the first active power reference value.

17. The apparatus according to claim 16, wherein the control device is further configured to:
generate a first status signal that is representative of an insulating contamination if the calculated active power is below the first active power reference value; and/or
generate a second status signal that is representative of a conductive contamination if the calculated active power is above the first active power reference value.

18. The apparatus according to claim 16, wherein the first active power reference value is factory-set or is adjustable by the user.

19. The apparatus according to claim 15, wherein the apparatus comprises at least one discharge electrode resistor, via which a metal profile or an insulatedly embedded conductor is connected to the earth terminal, and wherein the apparatus is configured so as to measure a voltage drop via the discharge electrode resistor, wherein the control device is configured so as to determine the partial current based on the voltage drop via the discharge electrode resistor.

20. The apparatus according to claim 15, wherein the apparatus comprises a transformer, which can be connected on the secondary side to the electrode assembly, and wherein the control device is connected to the transformer on the secondary side, in particular via a voltage divider, and is configured so as to determine the secondary voltage of the transformer.

21. The apparatus according to claim 15, wherein the apparatus is configured so as to simultaneously monitor a plurality of discharge electrodes, and wherein the control device is configured so as to detect for each discharge electrode a partial current that is coupled from the at least one emission peak of the respective discharge electrode to the earth terminal.

22. The apparatus according to claim 15, wherein the control device is configured to detect the partial current capacitively coupled from the emission peak to the metal profile or to the insulatedly embedded conductor and consequently to the earth terminal.

23. The apparatus according to claim 15, wherein the detection of the partial current (i1(t), i2(t), i3(t)) occurs selectively and independently of the signal generation and evaluation for contamination detection for any number of discharge electrodes.

24. The apparatus according to claim 15, wherein the control device is further configured to determine a contamination-based active resistance by quadrating a secondary voltage of the transformer divided by a contamination-based active power.

25. The apparatus according to claim 15, wherein the detected partial current (i1(t), i2(t), i3(t)) for generation of the status signal is independent of a DC component, which must flow to the ground upon discharge of highly charged surfaces via the emission peak and secondary coil of a transformer.

26. The apparatus according to claim 15, wherein the apparatus comprises a display for indicating the status signal in an analog or digital manner.

27. The apparatus according to claim 15, wherein the apparatus comprises a plurality of electrode assemblies and the status signal comprises separate status data for each electrode assembly.

28. A method for monitoring contaminations on discharge electrodes that serve for touchless discharge of electrically charged surfaces, wherein the discharge electrodes comprise at least one emission peak, and wherein the method comprises:
detecting a partial current (i1(t), i2(t), i3(t)) coupled from the at least one emission peak to the ground connected to the discharge electrode;
determining an active power based on the partial current (i1(t), i2(t), i3(t)); and
generating a status signal based on the calculated active power (i1(t), i2(t), i3(t)).
